(19) United States
(12) Patent Application Publication
(10) Pub. No.: US 2026/0107830 A1
(43) Pub. Date: Apr. 16, 2026

(54) RING STRUCTURES FOR INTEGRATED CIRCUIT PACKAGES

(71) Applicant: Taiwan Semiconductor Manufacturing Co., Ltd., Hsinchu (TW)

(72) Inventors: Chien-Chang Lin, New Taipei City (TW); Hung-Min Chang, Hsinchu (TW); Hsuan-Cheng Kuo, Hsinchu (TW); Wei-Wei Liang, Hsinchu (TW)

(21) Appl. No.: 19/049,912

(22) Filed: Feb. 10, 2025

Related U.S. Application Data
(60) Provisional application No. 63/706,820, filed on Oct. 14, 2024.

(51) Int. Cl. H01L 23/18; H01L 21/48; H01L 23/00; H01L 23/06; H01L 23/373; H01L 23/498; H01L 23/538; H01L 25/16; H10B 80/00; H10D 80/30

(52) U.S. Cl. CPC H10W 76/42; H10W 70/093; H10W 70/611; H10W 76/17; H10W 90/00; H10W 90/401; H10W 90/701; H10B 80/00; H10D 80/30; H10W 40/258; H10W 72/01257; H10W 72/01323; H10W 74/15; H10W 90/724; H10W 90/734

(57) ABSTRACT

In some embodiments, a device includes a chip-on-interposer structure on a first side of a package substrate, and a first ring structure on the first side of the package substrate. The first ring structure extends around a perimeter of the chip-on-interposer structure. A lid may be disposed on the first ring structure. The device may also include an array of connectors on a second side of the package substrate, wherein the second side of the package substrate is opposite a first side of the package substrate. A second ring structure may be on the second side of the package substrate. The second ring structure is positioned around a perimeter of the array of connectors.

### PRIORITY CLAIM AND CROSS-REFERENCE

This application claims the benefit of U.S. Provisional Application No. 63/706,820, filed on Oct. 14, 2024, which application is hereby incorporated herein by reference.

### BACKGROUND

Since the invention of the integrated circuit (IC), the semiconductor industry has experienced rapid growth due to continuous improvements in the integration density of various electronic components (i.e., transistors, diodes, resistors, capacitors, etc.). For the most part, this improvement in integration density has come from repeated reductions in minimum feature size, which allows more components to be integrated into a given area.

In an attempt to further increase circuit density, three-dimensional (3D) ICs have been investigated. In a typical formation process of a 3D IC, two dies are bonded together and electrical connections are formed between each die and contact pads on a substrate. Interposer stacking is part of 3D IC technology, where a Through-Silicon-Via (TSV) embedded interposer is connected to a silicon device with a micro bump.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-13 are views of intermediate stages in the manufacturing of an integrated circuit package, in accordance with some embodiments.

FIG. 14 illustrates an implementation of the integrated circuit package in an electrical device, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

According to various embodiments, a back side ring structure is integrated onto the back side of a package substrate of an integrated circuit package. The back side ring structure may provide improved warpage control of the package and higher joint yield, such as for a ball grid array (BGA) of the package. The integrated circuit package may have a lidded package architecture, which may contribute to package warpage control. However, in some instances, the degree of warpage control provided by the package's lid may be limited, or additional forces may be needed in larger package designs to further control warpage. The back side ring structure may provide additional stiffening to the package beyond what is provided by the lid to further mitigate forces that may lead to package warpage.

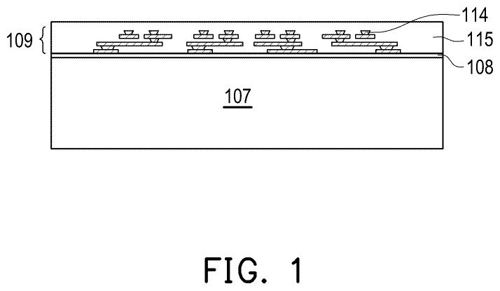

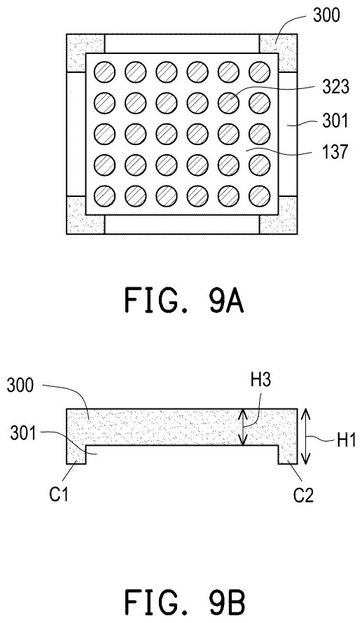

FIGS. 1-13 are views of intermediate stages in the manufacturing of an integrated circuit package, in accordance with some embodiments. FIGS. 1, 2, 3, 4, 5, 6, 7, 8, 9B, and 10B are cross-sectional views. FIGS. 9A, 10A, 11, 12, and 13 are top-down views, where some features are omitted for illustration clarity. A chip-on-interposer component is formed by bonding integrated circuit devices to a redistribution layer (RDL) interposer. The chip-on-interposer component is then mounted to a package substrate. Additionally, a back side ring structure is attached to the back side of the package substrate. The back side ring structure may provide improved warpage control of the resulting integrated circuit package. It is noted that the present disclosure is not limited to only the integrated circuit package that is provided in the supplied figures, as embodiments for the integrated package may include other three-dimensional integrated circuit (3DIC) packages not specifically depicted herein.

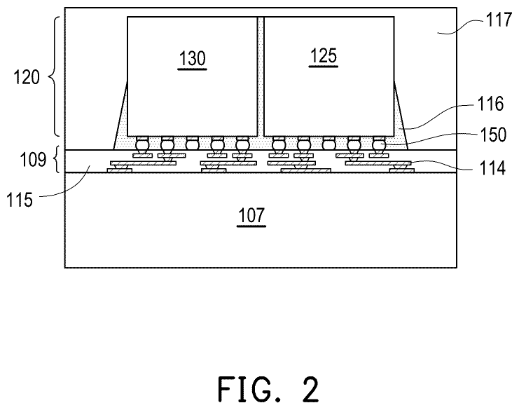

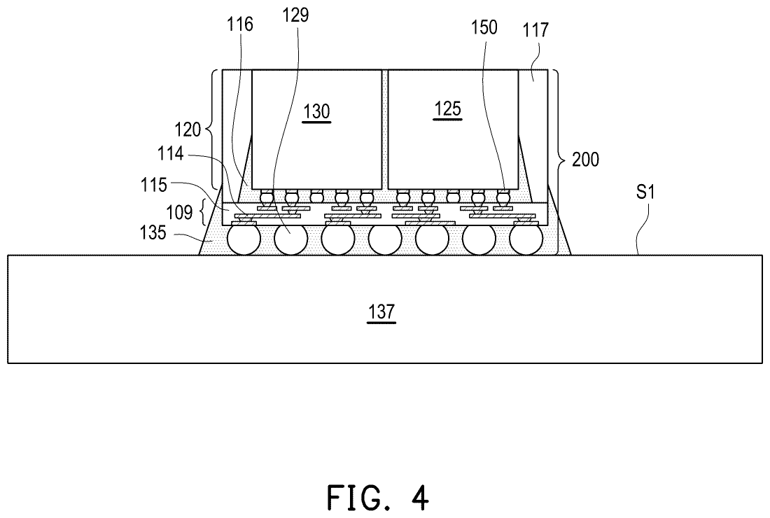

In FIG. 1, a redistribution layer (RDL) interposer 109 is formed on a first carrier substrate 107. The redistribution layer (RDL) interposer 109 includes one or more metal interconnect lines 114 that electrically connect subsequently bonded integrated circuit devices 120 (see FIG. 2) to a subsequently bonded package substrate 137 (see FIG. 4) for signal and/or power routing. The redistribution layer (RDL) interposer 109 includes one or more metal interconnect lines 114 that provide electrical connections, allowing bond pads on the subsequently formed integrated circuit devices to connect to leads or balls connecting the redistribution layer (RDL) interposer 109 to the package substrate 137. The bond pads for the integrated circuit devices 120 may be bonded to bond pads of the one or more metal interconnect lines 114.

The metal interconnect lines 114 may be formed in one or more layers of insulating material. In some embodiments, the one or more layers of insulating material in the redistribution layer (RDL) interposer 109 may have an organic composition. For example, the insulating material in the redistribution layer (RDL) interposer 109 may be a polymeric composition. In some examples, the insulating material in the redistribution layer (RDL) interposer 109 may be a polymer material, such as an epoxy. For example, the insulating material of the redistribution layer (RDL) interposer 109 may be an epoxy resin providing the matrix for a composite material, the composite material further including an amine based compound harder, filler materials including silica and/or alumina, flexabilizers, and/or curing agents. In other embodiments, the insulating material of the redistribution layer (RDL) interposer 109 may be a silicon containing inorganic material. In some embodiments, the insulating material in the redistribution layer (RDL) interposer 109 may have a dielectric constant of less than 3.5. For example, the insulating material in the redistribution layer (RDL) interposer 109 may have a dielectric constant of about 3.3.

The redistribution layer (RDL) interposer 109 may be formed using deposition processes, spin on processes, or the like forming the insulating materials, e.g., polymeric insulating materials. Openings and trenches for metal lines and/or traces may be formed using photolithography and etch processes. Further, a metal material, such as copper and/or aluminum, for the metal lines and/or traces may be formed using deposition processes, such as sputtering, plating processes, or the like. In some embodiments, the upper surface of the redistribution layer (RDL) interposer 109 (e.g., an upper layer of insulating material) may be planarized using a planarization process, such as chemical mechanical planarization (CMP).

In some embodiments, the redistribution layer (RDL) interposer 109 may be formed on a supporting first carrier substrate 107 through a bonding layer 108. The first carrier substrate 107 may be formed of any rigid material, e.g., metal, glass and/or semiconductor material (e.g., silicon (Si). In some embodiments, the bonding layer 108 may be a release film, which may be a Light-to-Heat Conversion (LTHC) layer.

In FIG. 2, chip-on-interposer processing is performed atop the redistribution layer (RDL) interposer 109. The chip-on-interposer structure is not limited to those specifically depicted in the supplied figures. For example, in some embodiments,, the chip-on-interposer structure may also be provided by System on Chip (SoC) type architecture and/or a System on Integrated Circuit (SoIC) type architecture.

In some embodiments, integrated circuit devices 120 are bonded to the upper surface of the redistribution layer (RDL) interposer 109. The integrated circuit devices 120 may include logic components 125 and/or memory components 130. For example, the logic components 125 may include a device die, a package with a device die(s) packaged therein, a System-on-Chip (SoC) or System-on-Integrated Circuit (SoIC) die including a plurality of integrated circuits (or device dies) integrated as a system, or the like. The device dies in the logic components 125 may be or may comprise processor dies, memory dies, input-output dies, Integrated Passive Devices (IPDs), the like, or combinations thereof. For example, the processor dies in chip-on-interposer components may be Central Processing Unit (CPU) dies, Graphic Processing Unit (GPU) dies, mobile application dies, Micro Control Unit (MCU) dies, BaseBand (BB) dies, Application Processor (AP) dies, or the like. The memory dies in logic components 125 may include Static Random-Access Memory (SRAM) dies, Dynamic Random-Access Memory (DRAM) dies, or the like. The device dies in logic components 125 may include semiconductor substrates and interconnect structures.

In some embodiments, the memory components 130 may include a memory stack, such as a High Bandwidth Memory (HBM) stack. In some other embodiments, the memory components 130 may include memory dies forming a die stack, and an encapsulant (such as a molding compound) encapsulating the memory dies therein.

In some embodiments, the integrated circuit devices 120, e.g., the logic components 125 and the memory components 130, may be bonded to the underlying redistribution layer (RDL) interposer 109, for example, through bonds 150. In accordance with some embodiments, the bonding is through a Chip-on-Wafer (CoW) bonding process, wherein the logic components 125 and the memory components 130, which are discrete chips/packages, are bonded to the redistribution layer (RDL) interposer 109. The bonds 150 may be solder bonds, direct bonds (e.g., metal-to-metal bonds), or the like.

FIG. 2 illustrates the bonding of the integrated circuit devices 120, e.g., the logic components 125 and the memory components 130, to the redistribution layer (RDL) interposer 109. The integrated circuit devices 120 may be bonded to the contacts on the redistribution layer (RDL) interposer 109 using a solder bonding/flip chip type process. The bonds 150 provide for connection between the contacts pads of the one or more metal interconnect lines 114 and the contact pads of the integrated circuit devices 120. In some embodiments, the solder bonding method may include micro-bumps, which may have a bump size of 25 microns or less. In some embodiments, the micro-bumps may also be formed of lead free materials, such as SnAg, SnCu, SnAgCu. In some other cases, the micro-bumps may be formed of PbAg. The bonds 150 may be formed using indirect bonding, mass reflow, thermal compression bonding, direct bonding, Cu-to-Cu diffusion bonding, insert bump bonding and combinations thereof. It is noted that the above micro-bump methods are provided for illustrative purposes only. Other examples of solder application methods include printing of solder paste, engraved mask stump, photosensitive organic mask and squeegee, electroplating of solder, evaporation, needle dispensing, solder paste printing, plated solder bumps, plated copper pillars with micro-bumps and combinations thereof.

After the application of solder to the contacts for the integrated circuit devices 120, the solder may then be contacted to the contacts on the contact pads of the one or more metal interconnect lines 114 under elevated temperature and pressure to effectuate bonding. Following bonding, an underfill 116 may be applied. The underfill 116 may be a thermoset epoxy or polymer that's applied to the bonds 150 to protect them and strengthen solder joints.

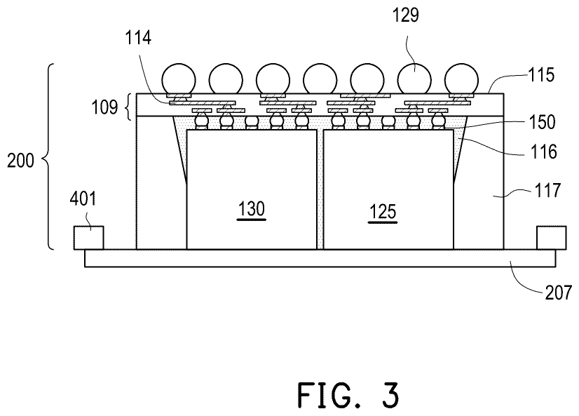

In some embodiments, the underfill 116 may be applied after the solder bumps have gone through a reflow oven and may be dispensed using an automated syringe. The underfill 116 may then be applied, in which the underfill 116 flows underneath the integrated circuit devices 120, e.g., the logic components 125 and the memory components 130, using capillary action. In some embodiments, after application, the underfill 116 is cured by being heated. In some embodiments, the structure including the integrated circuit devices 120 and the redistribution layer (RDL) interposer 109 may be referred to as a chip-on-interposer component 200 (as depicted in FIG. 3). It is noted that, while a single packaging component 125 and a single memory component 130 are depicted, any number of integrated circuit devices 120 may be included in the chip-on-interposer component 200. For example, the chip-on-interposer component 200 may include a plurality of packaging components 125 and a plurality of memory components 130.

Following the formation of the underfill 116, the structure may be encapsulated in an encapsulant 117, e.g., by over molding. For example, the structure including at least the integrated circuit devices 120, e.g., packaging components 125 and/or memory components 130, bonded to the redistribution layer (RDL) interposer 109, may be positioned within a mold, and a molding material may be injected into the mold to encapsulate the integrated circuit devices 120 to the redistribution layer (RDL) interposer 109. The molding material for the encapsulant 117 may be an epoxy material. For example, the epoxy material for the encapsulant may include an epoxy for the structural matrix of the compound, a phenolic hardener, a fused silica filler, a coupling agent, a curing promotor and a release agent. In some embodiments, the aforementioned materials for the encapsulant may work together to protect the integrated circuit devices 120, e.g., packaging components 125 and/or memory components 130, from environmental factors like moisture, heat, and physical stress, while also maintaining electrical insulation and structural integrity.

In FIG. 3, following hardening of the encapsulant 117, the hardened structure may be planarized, e.g., the encapsulant 117 may be planarized using chemical mechanical planarization to expose upper surfaces of the integrated circuit devices 120. The exposed planarized upper surface of the integrated circuit devices 120 may then be attached to a tape structure 207. For example, the planarized upper surface of the integrated circuit devices 120 may be attached to the tape structure 207, in which the tape structure 207 also includes a ring structure 401. The ring structure 401 may be a metal ring that provides support and stability for the tape structure 207 during and after a debonding process. In some embodiments, the tape structure 207 may be, e.g., a ultraviolet tape, although any other suitable adhesive or attachment may be used. In some embodiments, after the tape structure 207 is attached to the integrated circuit devices 120, e.g., the logic components 125 and the memory components 130, the first carrier substrate 107 (see FIG. 2) may be removed. For example, the first carrier substrate 107 may be debonded, for example, by projecting a laser beam on the release film, thus decomposing the release film. After removing the first carrier substrate 107, the back side surface of the redistribution layer (RDL) interposer 109 is exposed.

FIG. 3 illustrates one embodiment of a solder bond process applied to the chip-on-interposer component 200. In some embodiments, solder bumps 129 are formed on contacts to the one or more metal interconnect lines 114 of the redistribution layer (RDL) interposer 109. In some embodiments, the solder bumps 129 may be controlled collapse chip connection (C4) bumps. The solder bumps 129 may be used to bond the chip-on-interposer component 200 to a package substrate 137, as depicted in FIG. 4.

The term “solder”, as used herein, refers to any metal or metallic compound or alloy that is melted and then allowed to cool in order to join two or more metallic surfaces together. Generally speaking, solders have melting temperatures in the range of 150° C. to 250° C. Solder bumps may be small spheres of solder (solder balls) that are bonded to contact areas, interconnect lines or pads of semiconductor devices. In some embodiments, the solder bumps may be made from lead-free solder mixtures or lead tin solder.

In some embodiments, the solder bump process for forming the solder bonds may include an in-situ sputter clean to remove oxides or photoresist prior to metal deposition on the contacts to the one or more metal interconnect lines 114. The cleaning may also serve to roughen the surface of the contacts (also referred to as bond pads) in order to promote better adhesion of the under ball metallization (UBM). A metal mask may be used to pattern the structure for UBM and bump deposition. In some embodiments, a sequential evaporation of a chromium layer, a phased chromium/copper layer, a copper layer and a gold layer are deposited to form a thin film under ball metallurgy (UBM) on the contacts to the one or more metal interconnect lines 114. In one example, lead-tin solder is then evaporated on top of the UBMs to form thick layers of solder. The height of the resulting solder bumps are determined by the volume of the evaporated material that is deposited. This is also a function of the distance between the metal mask and the wafer, as well as the sizes of the mask openings. The deposited solder may be conical in shape, due to the way that the solder is formed in the openings of the solder mask. The solder may be reflowed to form spheres.

In FIG. 4, the chip-on-interposer component 200 of FIG. 3 is bonded to a first side S1 of a package substrate 137. The bonding may be by flip chip bonding (FCB). The package substrate 137 may be a cored substrate or a non-cored substrate. In some embodiments, the package substrate 137 may be a printed circuit board (PCB). A printed circuit board (PCB) is an electronic assembly that uses copper conductors to create electrical connections between components. In some embodiments, the PCB employed for the package substrate 137 may be built from alternating layers of conductive copper with layers of electrically insulating material. In some embodiments, the package substrate 137 may be a semiconductor material substrate, such as a type IV or type III-V semiconductor substrate. In one example, the package substrate 137 may be formed of a silicon containing material, e.g., a silicon (Si) substrate, or a germanium containing material, e.g., a silicon germanium (SiGe) substrate.

After the formation of the solder bumps 129, the structure, e.g., chip-on-interposer component 200, is flipped and the solder bumps 129 are aligned with contact pads (also referred to as bond pads) to the metal interconnect lines of the package substrate 137. In some embodiments, the accuracy of alignment may be of the order of a few microns for reliable function. Once a structure, e.g., chip-on-interposer component 200, is aligned and flipped on the package substrate 137, the solder bumps 129 are reflowed to spread the conductive material evenly across the bond pads of the package substrate 137. This improves the wettability of solder and reduces the gap or standoff between the chip-on-interposer component 200 and the package substrate 137.

Additionally, an underfill 135 may be formed between the chip-on-interposer component 200 and the package substrate 137. The underfill 135 may also be referred to as a chip on wafer (COW) molding. The underfill 135 may be deposited on the edges of the chip-on-interposer component 200, so that it flows across the gap between the chip-on-interposer component 200 and the package substrate 137 by capillary action, filling the space between the solder bumps 129. The underfill 135 depicted in FIG. 4 that is applied between the chip-on-interposer component 200 and the package substrate 137 may be similar to the underfill 116 that is formed between the integrated circuit devices 120 and the redistribution layer (RDL) interposer 109 that is illustrated in FIG. 3. Therefore, the description of the underfill 116 described above with reference to FIG. 3 is suitable for describing the underfill 135 that is present between the chip-on-interposer component 200 and the package substrate 137.

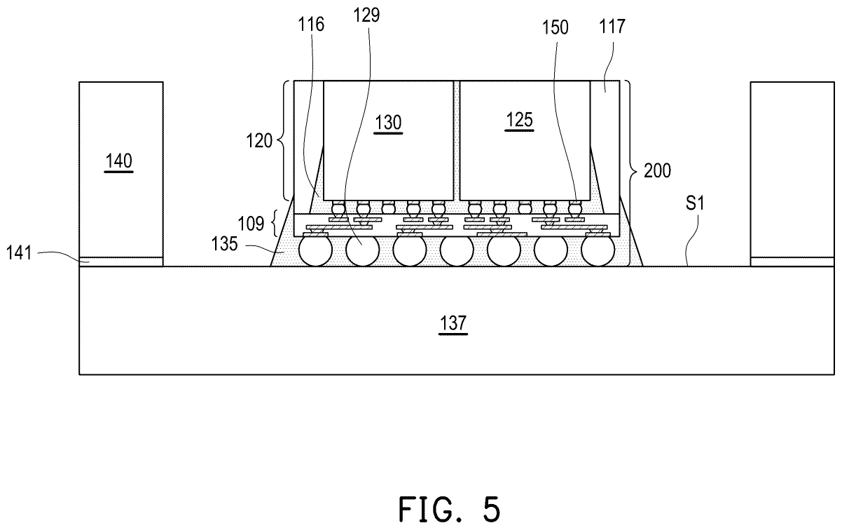

In FIG. 5, a first ring structure 140 is attached to the first side S1 of the package substrate 137. When the first side S1 of the package substrate 137 is the front side of the package substrate 137, the first ring structure 140 may be referred to as a front side ring structure. The first ring structure 140 may be a thermal ring, provided for thermal cooling of the device. The first ring structure 140 may be formed of a metal selected for heat dissipation performance, such as copper. However, any material that dissipates heat generated in the package of the chip-on-interposer component 200 and the package substrate 137 may be employed. The first ring structure 140 is positioned on the face of the package substrate 137 that the chip-on-interposer component 200 is bonded to. The first ring structure 140 is disposed around a perimeter of the chip-on-interposer component 200 in a top-down view.

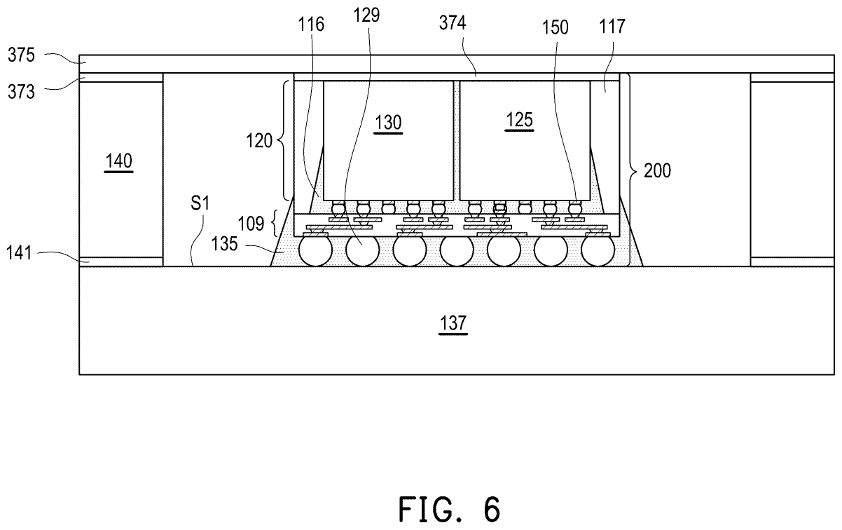

In FIG. 6, a lid 375 is attached to the first ring structure 140 and the chip-on-interposer component 200. In some embodiments, an adhesive material 373 is dispensed on the first ring structure 140. In some embodiments, the adhesive material 373 may comprise any material suitable for sealing a lid 375 onto the first ring structure 140, such as epoxies, urethane, polyurethane, silicone elastomers, and the like. The adhesive material 373 may be wet-dispensed to an outer portion or a periphery or edges of the first ring structure 140 by means of an adhesive dispenser.

Additionally, a thermal interface material (TIM) 374 may be applied to the top of the chip-on-interposer component 200 (e.g., the integrated circuit devices 120). The thermal interface material 374 may include but is not limited to, thermal grease, phase-change material, metal filled polymer matrix, and solder (e.g., alloys of lead, tin, indium, silver, copper, bismuth, and the like). If the thermal interface material 374 is a solid, it may be heated to a temperature at which it undergoes a solid to liquid transition and then may be applied in liquid form to the surface of the chip-on-interposer component 200. In some embodiments, the thermal interface material 374 may be wet-dispensed to the top of the integrated circuit devices 120 by a TIM dispenser having a stamp-type dispensing head. In some embodiments, the thermal interface material 374 may be applied to a top surface of the integrated circuit devices 120 by stencil printing.

In some embodiments, after the thermal interface material 374 is applied to the chip-on-interposer component 200, the lid 375 may be engaged to at least one of the adhesive material 373 that is present on the first ring structure 140 and the thermal interface material 374 that is present on the integrated circuit devices 120. In some embodiments, the lid 375 may be constructed from a thermally conductive material, such as copper, copper alloys, aluminum, aluminum alloys, cobalt, nickel and combinations and alloys thereof. However, the lid may be formed of any other suitable materials for application of the present disclosure. For example, materials for the lid 375 may be selected for their coefficient of thermal expansion (CTE). In some embodiments, the lid 375 may have a composition that is selected to have thermal expansion properties that mitigate forces that result in warpage of the chip-on-interposer component 200 and/or the package substrate 137. For example, the composition for the material of the lid 375 may be selected to have a coefficient of thermal expansion (CTE) that ranges from 10 ppm/° C. to 25 ppm/° C. In some embodiments, the lid 375 may have a composition that is selected for dissipating heat. For example, the composition for the lid 375 may have a high thermal conductivity (Tk), for example, between about 200 W/m·K to about 400 W/m·K or more, and may act as a heat spreader for dispersing heat generated from devices in the package structure.

The lid 375 is positioned over the integrated circuit devices 120 and the first ring structure 140. In some embodiments, the lid 375 may be positioned onto the integrated circuit devices 120 and the first ring structure 140 using a pick-and-place tool. In some embodiments, the lid 375 may be placed on top of the adhesive material 373 and on top of the TIM 374 to encapsulate and protect the integrated circuit devices 120. It is understood that additional processes may be performed before, during, or after the adhesive and/or TIM application processes to complete the fabrication of the integrated circuit package, but these additional processes are not discussed herein in detail for the sake of simplicity. For example, heat may be applied to the integrated circuit package to cure the structure by increasing the temperature of the TIM 374 and the adhesive material 373.

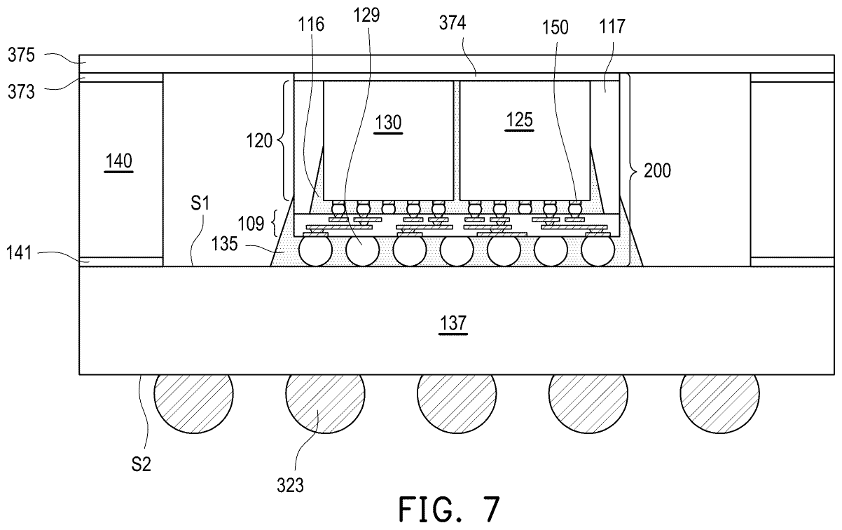

In FIG. 7, an array of connectors 323 is formed on the opposite side of the package substrate 137 (e.g., PCB) from the first side S1 that the chip-on-interposer component 200 is deposited on. For example, the chip-on-interposer component 200 may be positioned on a first side S1 of the package substrate 137, and the array of connectors 323 may be positioned on a second side S2 of the package substrate 137, in which the first side S1 and the second side S2 are opposing sides of the package substrate 137. In some embodiments, the first side S1 is the front side of the package substrate 137 and the second side S2 is the back side of the package substrate 137. In some embodiments, the array of connectors 323 may include a plurality of solder bumps. The array may be arranged in a series of rows and columns of solder bumps. In some embodiments, the array of connectors 323 may be a ball grid array (BGA). In some embodiments, a ball grid array (BGA) may be formed by attaching solder balls to the underside of the integrated circuit package, e.g., the second side S2 of the package substrate 137. The solder balls of the ball grid array (BGA), once reflowed, may make electrical connections to the electrical connections of the package substrate 137. During a reflow process, the solder may melt and self-align due to surface tension, creating connections to the package substrate 137.

In some embodiments, forming a ball grid array for the array of connectors 323 may include solder ball placement and a final reflow soldering step. Preparation of the package substrate 137 may include forming copper pads arranged in a grid pattern where the solder balls will be placed. This pattern may correspond to the desired connection points on the electrical device to which the integrated circuit package will be ultimately connected. In some embodiments, solder ball placement may include forming solder spheres on the pads on the package substrate 137, which may include using a flux to ensure proper adhesion. The reflow process may include the use of a reflow oven where the solder balls melt, allowing the array of connectors 323 for the ball grid array (BGA) to align and attach to the second side S2 of the package substrate 137, e.g., due to surface tension.

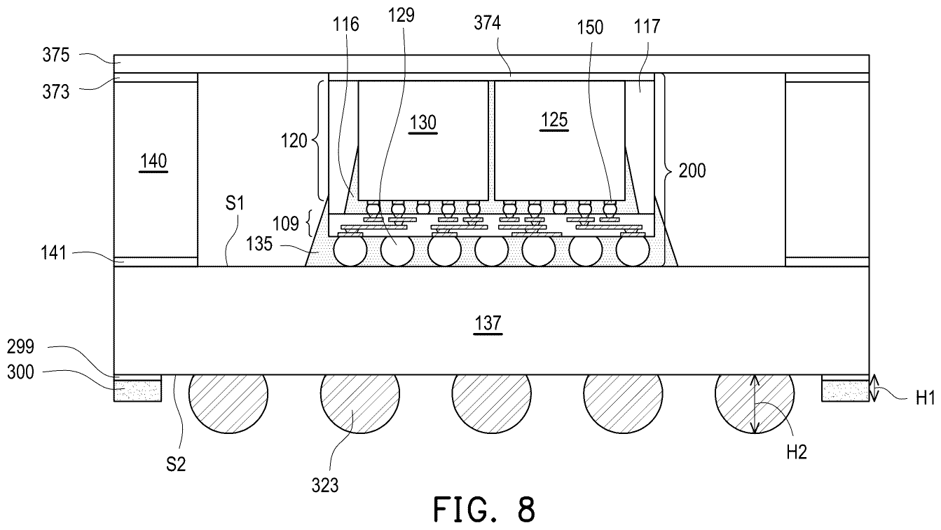

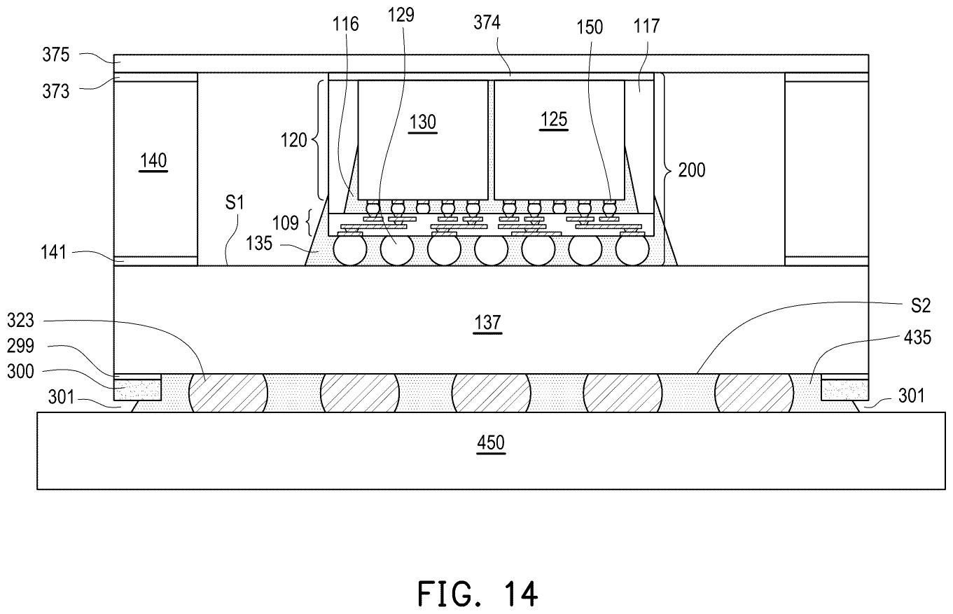

In FIG. 8, a second ring structure 300 is attached to the second side S2 of the package substrate 137. When the second side S2 of the package substrate 137 is the back side of the package substrate 137, the second ring structure 300 may be referred to as a back side ring structure. The second ring structure 300 extends around a perimeter of the array of connectors 323. The second ring structure 300 may be formed of a material that provides for improved warpage control of the integrated circuit package, e.g., warpage control of the package substrate 137 and/or the chip-on-interposer component 200. The second ring structure 300 may facilitate higher joint yield, e.g., a higher joint yield for the ball grid array (BGA) to the subsequently connected electrical device substrate 450 (as depicted in FIG. 14).

In some embodiments, the second ring structure 300 may have a multi-sided geometry that surrounds the perimeter of the array of connectors 323 in a top-down view. The multi-sided geometry may include a polygon shape, such as a square or rectangular configuration. In some aspects, each side of the second ring structure 300 may be straight in a top-down view.

In some embodiments, the second ring structure 300 may be formed of a metal such as copper, copper alloys, aluminum, aluminum alloys, nickel, cobalt, and combinations and alloys thereof. However, the second ring structure 300 may be formed of any other suitable materials that may offset, mitigate, and/or reduce warpage in the package substrate 137 and/or the chip-on-interposer component 200 by providing a material having a coefficient of thermal expansion (CTE) that counters the warpage forces in the package substrate 137 and/or the chip-on-interposer component 200. For example, the composition for the material of the second ring structure 300 may be selected to have a coefficient of thermal expansion (CTE) that ranges from 10 ppm/° C. to 25 ppm/° C. In some embodiments, the second ring structure 300 may be formed using stamping, cutting, grinding, or the like. The CTE of the second ring structure 300 may be lower than the CTE of the package substrate 137 and/or the CTE of the chip-on-interposer component 200.

In some embodiments, the second ring structure 300 may be connected to the second side S2 of the package substrate 137 using an adhesive layer 299. In some embodiments, the adhesive layer 299 is dispensed on the second ring structure 300 and/or the second side S2 of the package substrate 137. In some embodiments, the adhesive layer 299 may comprise any material suitable for connecting the second ring structure 300 to the second side S2 of the package substrate 137, such as epoxies, urethane, polyurethane, silicone elastomers, or the like. It is understood that additional processes may be performed before, during, or after the adhesive application processes to complete the fabrication of the integrated circuit package, but these additional processes are not discussed herein in detail for the sake of simplicity. For example, heat may be applied to the integrated circuit package to cure the structure by increasing the temperature of the adhesive layer 299.

In some embodiments, the second ring structure 300 has a first height H1 that is less than a second height H2 of the array of connectors 323. The height of the second ring structure 300 and the array of connectors 323 is measured from the second side S2 of the package substrate 137. For example, the second height H2 for the array of connectors may range from 0.2 mm and 0.5 mm. The first height H1 may be selected to allow for an underfill material to be injected through an opening that is defined by a space between the second ring structure 300 and a subsequently connected electrical device substrate 450 (as depicted in FIG. 14).

FIGS. 9A-13 illustrate some embodiments of geometries for the second ring structure 300. The geometry for the second ring structure 300 may be selected to facilitate the application of an underfill to the array of connectors 323, and may be selected to position the underfill in regions of the structure including the package substrate 137 and the chip-on-interposer component 200 to mitigate forces that may result in warpage.

FIGS. 9A and 9B illustrate a multi-sided second ring structure 300, wherein the second ring structure 300 includes a slot 301 in each sidewall. In the embodiments depicted in FIG. 9A, the multi-sided second ring structure 300 may have a quadrilateral geometry, such as a square perimeter geometry or a rectangular perimeter geometry. The perimeter geometry of the multi-sided second ring structure 300 may completely surround the array of connectors 323 in the integrated circuit package. Although, the geometries depicted in FIGS. 9A and 9B include four sides, the second ring structure 300 is not limited to only this example. For example, the multi-sided second ring structure 300 may have more than four sides. For example, in a top-down view, the second ring structure 300 may have the geometry of a hexagon, heptagon, octagon, enneagon, decagon, and geometries having a greater or lesser number of sides.

FIG. 9B illustrates that the portions of the sidewalls of the second ring structure 300 including the slot 301 have a third height H3 that is less than the first height H1 at the corners of the second ring structure 300. In the embodiment that is depicted in FIG. 9B, only a single slot 301 is present between the corners of the second ring structure 300. In some embodiments, a slot 301 may provide an opening in the sidewall that extends from a first corner C1 of the sidewall to a second corner C2 of the sidewall. The reduced height H3 of the sidewall including the slot 301 may facilitate the application of an underfill to the array of connectors 323 (see FIG. 9A). Additionally, when the array of connectors 323, e.g., ball grid array, is being bonded to an electrical device substrate 450 (as depicted in FIG. 14), the sidewall portion of the second ring structure 300 having the first height H1 may contact the electrical device substrate 450, wherein the slot 301 allows for the application of the underfill through the second ring structure 300 to the array of connectors 323. In this embodiment, the direct contact of the second ring structure 300 to the electrical device substrate 450 and the package substrate 137 provides a bridge to stabilize spacing between the substrates during reflow of the solder for the array of connectors 323.

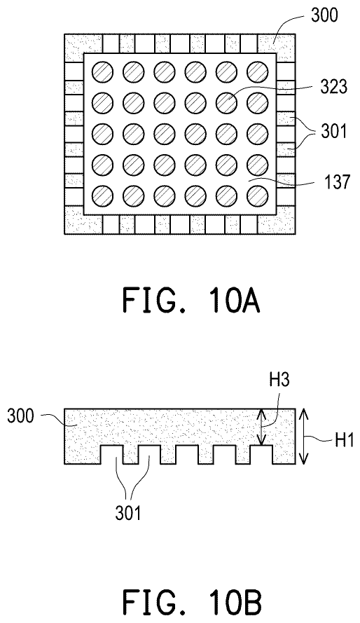

FIGS. 10A and 10B illustrate another embodiment of the second ring structure 300. In the embodiment depicted in FIGS. 10A and 10B, the sidewalls of the second ring structure 300 include a plurality of slots 301. Each slot 301 is present in a portion of a sidewall for the second ring structure 300 have the third height H3, and each slot 301 is separated from adjacent slots 301 by a portion of the sidewall for the second ring structure 300 having the first height H1. Although the sidewall of the second ring structure 300 depicted in FIG. 10B has five slots 301, the second ring structure 300 is not limited to only this embodiment, as each sidewall of the second ring structure 300 may have any number of slots 301.

Similar to the embodiment described above with reference to FIG. 9B, when the array of connectors 323, e.g., ball grid array, is being bonded to an electrical device substrate 450 (as depicted in FIG. 14), the sidewall portions of the second ring structure 300 having the first height H1 depicted in FIG. 10B may contact the electrical device substrate 450, wherein the plurality of slot 301 allow for the application of an underfill through the second ring structure 300 to the array of connectors 323. In this embodiment, the direct contact of the second ring structure 300 to the electrical device substrate 450 and the package substrate 137 provides a bridge to stabilize spacing between the substrates during reflow of the solder for the array of connectors 323.

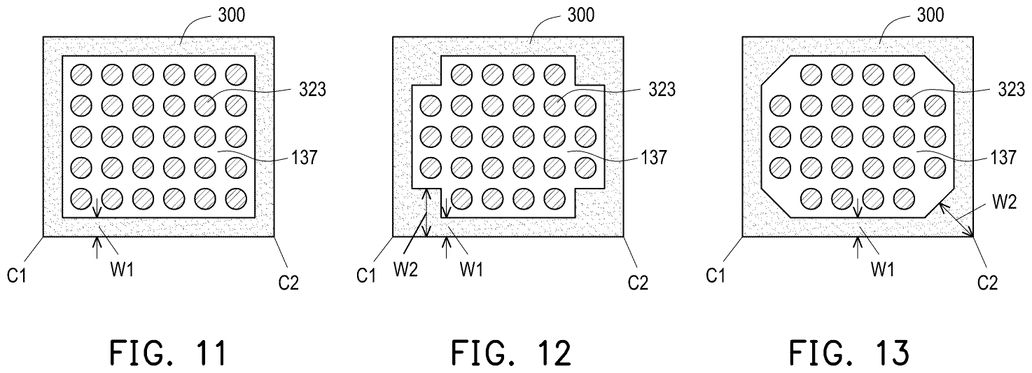

FIG. 11 illustrates another embodiment of a second ring structure 300. For example, the height of the second ring structure 300 along the sidewalls is continuously equal to the first height H1 (as depicted in FIG. 8). In some embodiments, the sidewall width W1 (also referred to as first width W1) of the second ring structure 300 that is illustrated in FIG. 11 is uniform and continuous along the length of each sidewall. For example, the sidewall width W1 is the same from the inner edge of a first corner C1 to an inner edge of an opposing second corner C2 for each side of the second ring structure 300.

FIG. 12 illustrates another embodiment of a second ring structure 300 in which the sidewall width in the corners C1, C2 of the second ring structure 300 is greater than the width of the portion of the sidewall that is between the corners C1, C2 of the second ring structure 300. For example, the second ring structure 300 may include a second width W2 in the corners C1, C2 of the second ring structure 300 that is greater than a fist width W1 for the portion of the sidewall of the second ring structure 300 that is between the corners C1, C2 for each sidewall of the second ring structure 300. In one example, the corners C1, C2 for the second ring structure 300 may have rectangular or square shaped columns on the interior face of the second ring structure 300.

FIG. 13 illustrates another embodiment of a second ring structure 300 in which the corners C1, C2 have triangular shaped columns on the interior face of the second ring structure 300. FIG. 13 illustrates another embodiment of a second ring structure 300 in which the sidewall width in the corners C1, C2 of the second ring structure 300 is greater than the width of the portion of the sidewall that is between the corners C1, C2 of the second ring structure 300. In an embodiment, the second ring structure 300 includes a non-uniform width at each corner C1, C2.

In the embodiments of FIGS. 11-13, the sidewalls of the second ring structure 300 are free of slots. Thus, the sidewalls of the second ring structure 300 depicted in each of FIGS. 11-13 are free of slots. For example, the height of the second ring structure 300 along the sidewalls of the second ring structure 300 is continuously equal to the first height H1. In other embodiments, the sidewalls of the second ring structure 300 of FIGS. 11-13 also include one or more slots 301.

FIG. 14 illustrates an implementation of the integrated circuit package in an electrical device, in accordance with some embodiments. In particular, the package substrate 137 may be connected to an electrical device substrate 450, such as a circuit board (e.g., a motherboard). FIG. 14 further illustrates bonding the array of connectors 323 to the electrical device substrate 450, and applying an underfill material 435 to the array of connectors 323 through a slot 301 in the second ring structure 300.

In some embodiments, the underfill material 435 may be applied to the underside of the array of connectors 323, e.g., BGA, to provide additional mechanical support and protect the solder joints from stress. The underfill material 435 may be in contact with the inner edges of the second ring structure 300, and it may flow across the gap between the package substrate 137 and the electrical device substrate 450 by capillary action, filling the space between the connectors 323. The underfill material 435 depicted in FIG. 14 may be similar to the underfill 116 that is positioned between the integrated circuit devices 120 and the redistribution layer (RDL) interposer 109 that is illustrated in FIG. 3. Therefore, the description of the underfill 116 described above with reference to FIG. 3 is suitable for describing the underfill material 435 that is present between the package substrate 137 and the electrical device substrate 450.

In some embodiments, the second ring structure 300 acts as a dam for containing the underfill material 435 around the array of connectors 323, e.g., ball grid array. The slots 301 illustrated in FIGS. 9A-10B provide additional access for the underfill material 435 to be applied to the array of connectors 323. Although not separately illustrated in FIG. 14, it should be appreciated that, for the embodiments of the second ring structure 300 described with reference to FIGS. 9A-10B, when the array of connectors 323, e.g., ball grid array, is being bonded to the a electrical device substrate 450, the sidewall portion of the second ring structure 300 having the first height H1 may contact the electrical device substrate 450, wherein the slot 301 (as depicted in FIG. 9B) or the plurality of slots 301 (as depicted in FIG. 10B) allows for the application of the underfill through the second ring structure 300 to the array of connectors 323. In this embodiment, the direct contact of the second ring structure 300 to the electrical device substrate 450 and the package substrate 137 provides a bridge to stabilize spacing between the substrates during reflow of the solder for the array of connectors 323.

In some embodiments, the second ring structure 300 may provide for better warpage control of the integrated circuit package and higher joint yield, e.g., a high joint yield for the array of connectors 323. The second ring structure 300 may also provide additional stiffening to the lid 375, to further mitigate forces that may lead to warpage in the integrated circuit package.

In accordance with an embodiment, a method includes bonding a chip-on-interposer structure onto a package substrate; bonding a first ring structure a first side of the package substrate, wherein the first ring structure extends around a perimeter of the chip-on-interposer structure; bonding a lid to the first ring structure and the chip-on-interposer structure; forming an array of connectors on a second side of the package substrate, wherein the second side of the package substrate is opposite the first side of the package substrate; and bonding a second ring structure to the second side of the package substrate, wherein the second ring structure extends around a perimeter of the array of connectors. In an embodiment, the chip-on-interposer structure comprises integrated circuit dies bonded to a redistribution layer interposer. In an embodiment, the array of connectors comprises a ball grid array (BGA). In an embodiment, a coefficient of thermal expansion of the second ring structure is less than a coefficient of thermal expansion of the package substrate. In an embodiment, the second ring structure comprises copper, aluminum, cobalt, or nickel, and wherein the lid comprises copper, aluminum, cobalt, or nickel. In an embodiment, bonding the second ring structure to the second side of the package substrate comprises attaching the second ring structure to the second side of the package substrate through an adhesive layer. In an embodiment, the second ring structure has a first height that is less than a second height of the array of connectors. In an embodiment, the method may further include bonding the array of connectors to an electrical device substrate; and applying an underfill to the array of connectors, wherein the second ring structure comprises an opening and the underfill is applied through the opening.

In accordance with another embodiment, a device includes a package substrate; a chip-on-interposer structure on a first side of the package substrate; a ball grid array on a second side of the package substrate, wherein the second side of the package substrate is opposite the first side of the package substrate; and a ring structure on the second side of the package substrate, the ring structure extending around a perimeter of the ball grid array, wherein the ring structure has a first height that is less than a second height of the ball grid array. In an embodiment, the chip-on-interposer structure comprise a high bandwidth memory (HBM) stack, a system on chip (SoC) component, or a system on integrated circuit (SoIC) component. In an embodiment, a coefficient of thermal expansion of the ring structure is less than a coefficient of thermal expansion of the package substrate. In an embodiment, the ring structure comprises copper, aluminum, cobalt, or nickel. In an embodiment, the ring structure has a multi-sided geometry in a top-down view, wherein a sidewall of the multi-sided geometry comprises edges having the first height and at least one opening in the sidewall having a third height, wherein the third height is less than the first height. In an embodiment, the at least one opening in the sidewall is a single opening that extends from a first corner of the sidewall to a second corner of the sidewall. In an embodiment, the ring structure has a first thickness at the first corner and the second corner and has a second thickness in sidewall portions between the first corner and the second corner, and wherein the first thickness is greater than the second thickness.

In accordance with yet another embodiment, a device includes a chip-on-substrate structure on a first side of a package substrate; a first ring structure on the first side of the package substrate, wherein the first ring structure extends around a perimeter of the chip-on-substrate structure; a lid on the first ring structure; an array of connectors on a second side of the package substrate, wherein the second side of the package substrate is opposite the first side of the package substrate; and a second ring structure on the second side of the package substrate, the second ring structure extending around a perimeter of the array of connectors. In an embodiment, the array of connectors comprises a ball grid array, the second ring structure having a first height that is greater than a second height of the ball grid array. In an embodiment, the second ring structure has a coefficient of thermal expansion ranging from 10 ppm/° C. to 25 ppm/° C. In an embodiment, the second ring structure comprises copper, aluminum, cobalt, or nickel. In an embodiment, the lid comprises copper, aluminum, cobalt, or nickel.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
bonding a chip-on-interposer structure onto a package substrate;
bonding a first ring structure a first side of the package substrate, wherein the first ring structure extends around a perimeter of the chip-on-interposer structure;
bonding a lid to the first ring structure and the chip-on-interposer structure;
forming an array of connectors on a second side of the package substrate, wherein the second side of the package substrate is opposite the first side of the package substrate; and
bonding a second ring structure to the second side of the package substrate, wherein the second ring structure extends around a perimeter of the array of connectors.

2. The method of claim 1, wherein the chip-on-interposer structure comprises integrated circuit dies bonded to a redistribution layer interposer.

3. The method of claim 1, wherein the array of connectors comprises a ball grid array (BGA).

4. The method of claim 1, wherein a coefficient of thermal expansion of the second ring structure is less than a coefficient of thermal expansion of the package substrate.

5. The method of claim 1, wherein the second ring structure comprises copper, aluminum, cobalt, or nickel, and wherein the lid comprises copper, aluminum, cobalt, or nickel.

6. The method of claim 1, wherein bonding the second ring structure to the second side of the package substrate comprises attaching the second ring structure to the second side of the package substrate through an adhesive layer.

7. The method of claim 1, wherein the second ring structure has a first height that is different than a second height of the array of connectors.

8. The method of claim 7, further comprising:
bonding the array of connectors to an electrical device substrate; and
applying an underfill to the array of connectors, wherein the second ring structure comprises an opening and the underfill is applied through the opening.

9. A device comprising:
a package substrate;
a chip-on-interposer structure on a first side of the package substrate;
a ball grid array on a second side of the package substrate, wherein the second side of the package substrate is opposite the first side of the package substrate; and
a ring structure on the second side of the package substrate, the ring structure extending around a perimeter of the ball grid array, wherein the ring structure has a first height that is different than a second height of the ball grid array.

10. The device of claim 9, wherein the chip-on-interposer structure comprise a high bandwidth memory (HBM) stack, a system on chip (SoC) component, or a system on integrated circuit (SoIC) component.

11. The device of claim 9, wherein a coefficient of thermal expansion of the ring structure is different than a coefficient of thermal expansion of the package substrate.

12. The device of claim 9, wherein the ring structure comprises copper, aluminum, cobalt, or nickel.

13. The device of claim 9, wherein the ring structure has a multi-sided geometry in a top-down view, wherein a sidewall of the multi-sided geometry comprises edges having the first height and at least one opening in the sidewall having a third height, wherein the third height is less than the first height.

14. The device of claim 13, wherein the at least one opening in the sidewall is a single opening that extends from a first corner of the sidewall to a second corner of the sidewall.

15. The device of claim 14, wherein the ring structure has a first thickness at the first corner and the second corner and has a second thickness in sidewall portions between the first corner and the second corner, and wherein the first thickness is greater than the second thickness.

16. A device comprising:
a chip-on-substrate structure on a first side of a package substrate;
a first ring structure on the first side of the package substrate, wherein the first ring structure extends around a perimeter of the chip-on-substrate structure;
a lid on the first ring structure;
an array of connectors on a second side of the package substrate, wherein the second side of the package substrate is opposite the first side of the package substrate; and
a second ring structure on the second side of the package substrate, the second ring structure extending around a perimeter of the array of connectors.

17. The device of claim 16, wherein the array of connectors comprises a ball grid array, the second ring structure having a first height that is greater than a second height of the ball grid array.

18. The device of claim 16, wherein the second ring structure has a coefficient of thermal expansion ranging from 10 ppm/° C. to 25 ppm/° C.

19. The device of claim 16, wherein the second ring structure comprises copper, aluminum, cobalt, or nickel.

20. The device of claim 16, wherein the lid comprises copper, aluminum, cobalt, or nickel.
